(19) United States
(12) Patent Application Publication
(10) Pub. No.: US 2026/0190671 A1
(43) Pub. Date: Jul. 2, 2026

(54) LIGHT EMITTING DISPLAY DEVICE

(71) Applicant: LG Display Co., Ltd., Seoul (KR)

(72) Inventors: Ji Sub PARK, Paju-si (KR); Kyung Mi KIM, Paju-si (KR); Byeong Gon KIM, Paju-si (KR)

(73) Assignee: LG Display Co., Ltd., Seoul (KR)

(21) Appl. No.: 19/406,117

(22) Filed: Dec. 2, 2025

(30) Foreign Application Priority Data
Dec. 31, 2024 (KR) 10-2024-0202830

(51) Int. Cl. H10K 59/124; H10K 59/35; H10K 59/80

(52) U.S. Cl. CPC H10K 59/124; H10K 59/353; H10K 59/80515

(57) ABSTRACT

A light emitting display device includes a substrate, a plurality of light emitting units, a light emitting element on the substrate, the light emitting element comprising a pixel electrode corresponding to one of the plurality of light emitting units, an intermediate layer on the pixel electrode, and a common electrode on the intermediate layer, and a curved structure between the substrate and the light emitting element. The curved structure may include a first curved layer at a corresponding light emitting unit and a second curved layer having a plurality of patterns disposed on the first curved layer and spaced apart from each other.

### CROSS-REFERENCE TO RELATED APPLICATIONS

This application claims the benefit of and priority to Korean Patent Application No. 10-2024-0202830, filed on Dec. 31, 2024, the entire contents of which are incorporated herein by reference for all purposes as if fully set forth herein.

### BACKGROUND

### 1. Technical Field

The present disclosure relates to a display device, and particularly to, for example, without limitation, a display device including a light emitting display device configured to improve perceived visibility by enhancing the light emitting efficiency of each light emitting unit and reducing luminance deviation caused by changes in viewing angle for each color.

### 2. Description of Related Art

Display devices configured to display images on products such as televisions, monitors, smartphones, tablets, and notebook computers employ various types and structures.

Such display devices do not require a separate light source, and compactness and vivid color representation are demanded. Accordingly, self-emissive display devices such as organic light emitting display devices or quantum dot light emitting display devices have emerged as competitive applications.

A self-emissive display device includes a plurality of pixels on a substrate, and each pixel includes a light emitting diode having two opposing electrodes and an emission layer disposed therebetween.

Various efforts have been made to enable a self-emissive display device to emit light with maximized light emitting efficiency of a light emitting element.

A display device is viewed not only from the front but also at an inclined angle, and a problem has arisen in that luminance significantly decreases when viewed at different viewing angles.

The description of related art should not be considered prior art merely because it is mentioned in or associated with this section. The description of related art includes information that describes one or more aspects of the subject technology, and the description in this section does not limit the scope of the present disclosure.

### SUMMARY

Accordingly, the present disclosure is directed to a light emitting display device that substantially obviates one or more problems due to limitations and disadvantages of the related art.

Embodiments of the present disclosure provide a light emitting display device that improves light emitting efficiency in a manner similar to Lambertian characteristics by applying a curved structure under a pixel electrode.

Embodiments of the present disclosure provide a light emitting display device that improves not only light emitting efficiency but also luminance characteristics according to changes in viewing angle by providing a curved structure including two layers stacked vertically in each of light emitting units.

Embodiments of the present disclosure provide a light emitting display device that meets customer requirements by setting the curvatures of first curved layers provided in respective light emitting units to be different from each other to vary luminance compensation for each color.

Embodiments of the present disclosure provide a light emitting display device that prevents luminance deviation for each color depending on viewing angle.

Embodiments of the present disclosure provide a light emitting display device that implements Environmental/Social/Governance (ESG) by improving light emitting efficiency and viewing angle-luminance characteristics without adding processes.

The aspects to be accomplished by the present disclosure are not limited to the above-mentioned aspects, and other aspects not mentioned herein will be clearly understood by those skilled in the art from the following description.

Additional advantages, aspects, and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

A light emitting display device according to an embodiment of the present disclosure includes a substrate, a plurality of light emitting units, a light emitting element on the substrate, the light emitting element comprising a pixel electrode corresponding to one of the plurality of light emitting units, an intermediate layer on the pixel electrode, and a common electrode on the intermediate layer, and a curved structure between the substrate and the light emitting element. The curved structure may comprise a first curved layer at one of the plurality of light emitting units and a second curved layer comprising a plurality of patterns disposed on the first curved layer and spaced apart from each other.

It is to be understood that both the foregoing general description and the following detailed description of the present disclosure are examples and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a schematic diagram showing a light emitting display device according to an embodiment of the present disclosure;

FIG. 2 is a cross-sectional view of a sub-pixel in which a plurality of curved patterns is applied to a light emitting unit;

FIG. 3 is a graph showing viewing angle-luminance characteristics for each color of the light emitting display device to which the structure shown in FIG. 2 is applied;

FIG. 4 is a cross-sectional view of a sub-pixel of a light emitting display device according to an embodiment of the present disclosure;

FIGS. 5A to 5C are graphs showing luminance according to the viewing angle depending on whether the curved structure shown in FIG. 4 is applied;

FIG. 6 is a cross-sectional view of the light emitting display device according to the embodiment of the present disclosure;

FIG. 7 is a diagram showing a pixel circuit corresponding to the sub-pixel shown in FIG. 6 according to an example; and

FIG. 8 illustrates graphs showing the viewing angle characteristics of third to sixth experimental examples.

### DETAILED DESCRIPTION

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on,” “above,” “under” and “next to,” at least one intervening element can be present between the two elements, unless “immediate(ly)” or “direct(ly)” or “close(ly)” is used. It will be understood that when an element or layer is referred to as being “connected to,” or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms are merely used to refer to one element separately from another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, a light emitting display device of the present disclosure will be described with reference to the accompanying drawings and example embodiments.

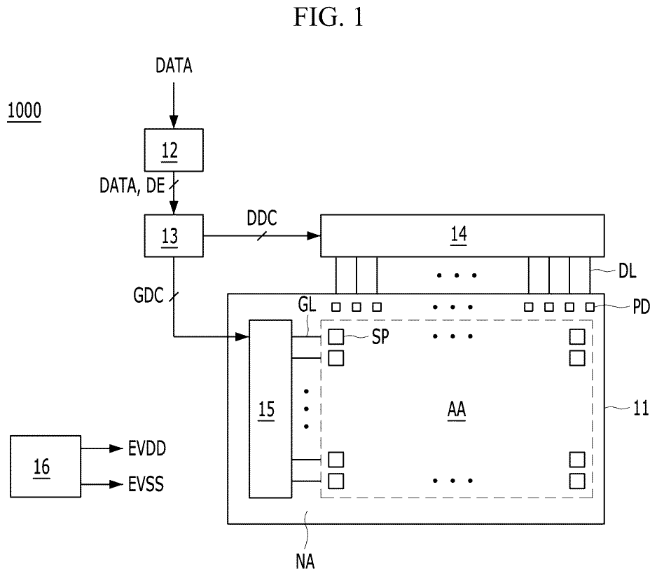

FIG. 1 is a schematic diagram showing a light emitting display device according to an embodiment of the present disclosure.

As shown in FIG. 1, a display device 1000 according to an embodiment of the present disclosure may include a display panel 11, an image processor 12, a timing controller 13, a data driver 14, a scan driver 15, and a power supply 16.

The display panel 11 may display an image in response to a data signal DATA supplied from the data driver 14, a scan signal supplied from the scan driver 15, and power supplied from the power supply 16.

The display panel 11 may include sub-pixels SP disposed at intersections of a plurality of gate lines GL and a plurality of data lines DL. The structure of the sub-pixels SP may vary depending on the type of display device 1000.

For example, the sub-pixels SP may be implemented in a top emission type, a bottom emission type, or a dual emission type, depending on the structure thereof. The sub-pixels SP refer to units capable of emitting light of their own colors with or without a specific type of color filter. For example, the sub-pixels SP may include red sub-pixels, green sub-pixels, and blue sub-pixels. Alternatively, the sub-pixels SP may include, for example, red sub-pixels, blue sub-pixels, white sub-pixels, and green sub-pixels. The sub-pixels SP may have one or more different emission areas depending on emission characteristics thereof. For example, blue sub-pixels and sub-pixels that emit other colors may have different emission areas.

One or more sub-pixels SP may constitute one unit pixel. For example, one unit pixel may include red, green, and blue sub-pixels, and the red, green, and blue sub-pixels may be repeatedly disposed. Alternatively, one unit pixel may include red, green, blue, and white sub-pixels, and the red, green, blue, and white sub-pixels may be repeatedly disposed or may be disposed in a quad type. However, the present disclosure is not limited thereto. In the embodiment according to the present disclosure, the color types, arrangement types, and arrangement orders of the sub-pixels may be configured in various forms depending on emission characteristics, lifespan of elements, or specifications of the device.

The display panel 11 may be divided into a display area AA (an area inside the dotted line) in which the sub-pixels SP are disposed to display an image and a non-display area NA surrounding the display area AA. The scan driver 15 may be mounted in the non-display area NA of the display panel 11. In addition, the non-display area NA may include a pad unit PAD including pad electrodes PD.

Hereinafter, the display area AA will be referred to as an active area, and the non-display area NA will be referred to as a non-active area.

The image processor 12 may output a data enable signal DE along with a data signal DATA supplied from the outside. In addition to the data enable signal DE, the image processor 12 may output at least one of a vertical sync signal, a horizontal sync signal, or a clock signal. However, illustration of these signals is omitted for convenience of description.

The timing controller 13 may receive the data signal DATA along with a driving signal from the image processor 12. The driving signal may include the data enable signal DE. Alternatively, the driving signal may include the vertical sync signal, the horizontal sync signal, and the clock signal. The timing controller 13 may output, based on the driving signal, a data timing control signal DDC for control of an operation timing of the data driver 14 and a gate timing control signal GDC for control of an operation timing of the scan driver 15.

The data driver 14 may sample and latch the data signal DATA supplied from the timing controller 13 in response to the data timing control signal DDC supplied from the timing controller 13, may convert the latched data signal into a gamma reference voltage, and may output the gamma reference voltage.

The data driver 14 may output the data signal DATA through the data lines DL. The data driver 14 may be implemented in the form of an integrated circuit (IC). For example, the data driver 14 may be electrically connected to the pad electrodes PD disposed in the non-active area NA of the display panel 11 via a flexible circuit film (not shown).

The scan driver 15 may output a scan signal in response to the gate timing control signal GDC supplied from the timing controller 13. The scan driver 15 may output the scan signal through the gate lines GL. The scan driver 15 may be implemented in the form of an integrated circuit (IC) or may be implemented on the display panel 11 in a gate-in-panel (GIP) manner.

The power supply 16 may output a high potential voltage and a low potential voltage for driving the display panel 11. The power supply 16 may supply the high potential voltage to the display panel 11 through a first power line EVDD (a driving power line or a pixel power line) and may supply the low potential voltage to the display panel 11 through a second power line EVSS (an auxiliary power line or a common power line).

The display panel 11 may be divided into the active area AA and the non-active area NA, and may include a plurality of sub-pixels SP defined by the gate lines GL and the data lines DL, which intersect each other in the form of a matrix in the active area AA.

The sub-pixels SP may include sub-pixels that emit at least two types of light among red light, green light, blue light, yellow light, magenta light, and cyan light. In addition, the plurality of sub-pixels SP may emit light of their own colors with or without a specific type of color filter. However, the present disclosure is not limited thereto. The color types, arrangement types, and arrangement orders of the sub-pixels SP may be configured in various forms depending on emission characteristics, lifespan of elements, or specifications of the device.

Each sub-pixel SP may include a light emitting unit from which light is emitted.

The light emitting display device according to the embodiment of the present disclosure is characterized by including a structure having a curvature below the light emitting element to enhance light emitting efficiency.

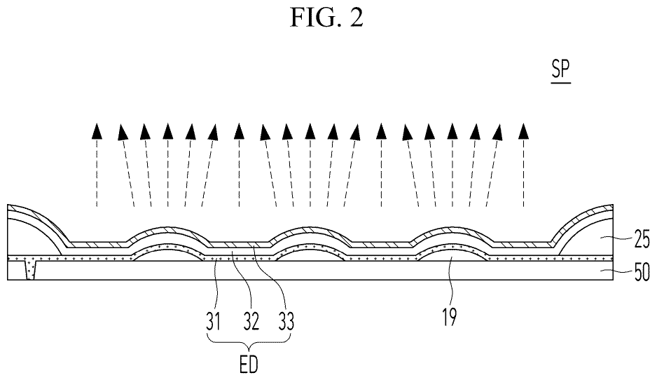

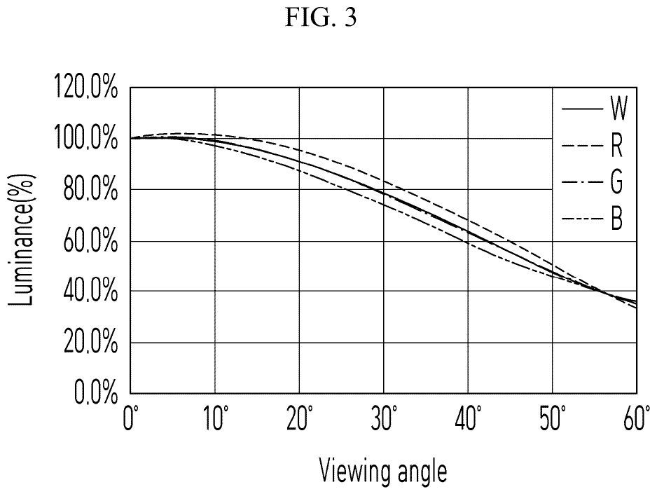

FIG. 2 is a cross-sectional view of a sub-pixel in which a plurality of curved patterns is applied to a light emitting unit. FIG. 3 is a graph showing viewing angle-luminance characteristics for each color of the light emitting display device to which the structure shown in FIG. 2 is applied.

As shown in FIG. 2, in the light emitting unit of a sub-pixel, a pixel electrode 31 spaced apart from other sub-pixels, an intermediate layer 32 stacked on the pixel electrode 31, and a common electrode 33 stacked on the intermediate layer 32 constitute a light emitting element ED on a thin-film transistor array 50. An emission region of the pixel electrode 31 of the light emitting element may be defined by an open region of a bank 25.

The light emitting display device shown in FIG. 2 is configured such that a plurality of curved structures 19 spaced apart from each other is applied to one light emitting unit.

The components of the light emitting element ED disposed on each curved structure 19 are formed along the curvature of the curved structure 19. That is, the pixel electrode 31, the intermediate layer 32, and the common electrode 33 are formed to have a corrugated shape along the curvature of the curved structure 19.

As shown in FIG. 2, when the light emitting element ED formed on the curved structure 19 having a curvature emits light upward, the light spreads in a region above the curved structure 19, thereby improving light emitting efficiency.

However, as shown in FIG. 3, in the above-described structure, luminance deviation is intensified when the light emitting display device is viewed at an increased viewing angle. In addition, decrease in luminance depending on the viewing angle differs for red, green, and blue. This indicates that luminance deviation depending on the viewing angle for each color varies according to the degree of shift in the outcoupling curve caused by differences in cavity effects for each color. For example, this means that, even when white is displayed with the same driving voltage, a difference in perceived color occurs between a white screen viewed from the front and a white screen viewed at an angle.

In FIG. 3, the viewing angle characteristic of red (R) represents the viewing angle characteristic of the red sub-pixel, the viewing angle characteristic of green (G) represents the viewing angle characteristic of the green sub-pixel, and the viewing angle characteristic of blue (B) represents the viewing angle characteristic of the blue sub-pixel.

The viewing angle characteristic of white (W) represents the viewing angle characteristic when all of the red, green, and blue sub-pixels are turned on. Because the contribution of green is dominant when white is displayed, the viewing angle characteristic of white substantially follows the viewing angle characteristic of the green sub-pixel.

Table 1 below shows color coordinate characteristics and luminance values of white according to viewing angles. It can be seen that, even when the structure shown in FIG. 2 is applied, luminance significantly decreases at large viewing angles.

TABLE 1

| Viewing Angle (°) | CIEu | CIEv | Luminance (%) |
|---|---|---|---|
| 30 | 0.1948 | 0.4599 | 78.2 |
| 45 | 0.1947 | 0.4634 | 55.4 |
| 60 | 0.1908 | 0.4642 | 34.7 |

The light emitting display device according to the embodiment of the present disclosure is characterized by vertically stacking a first curved layer and a second curved layer having different curvatures to enhance light emitting efficiency and compensate for luminance deviation according to the viewing angle.

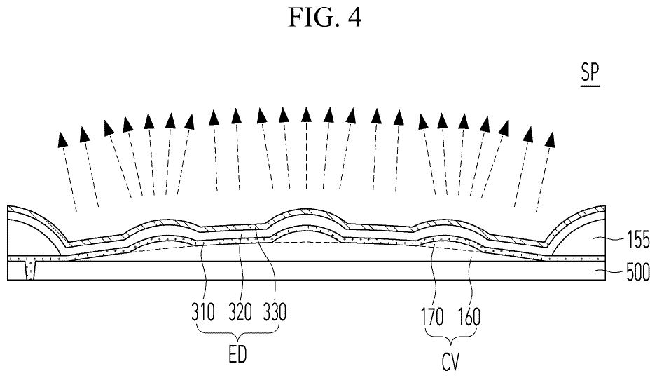

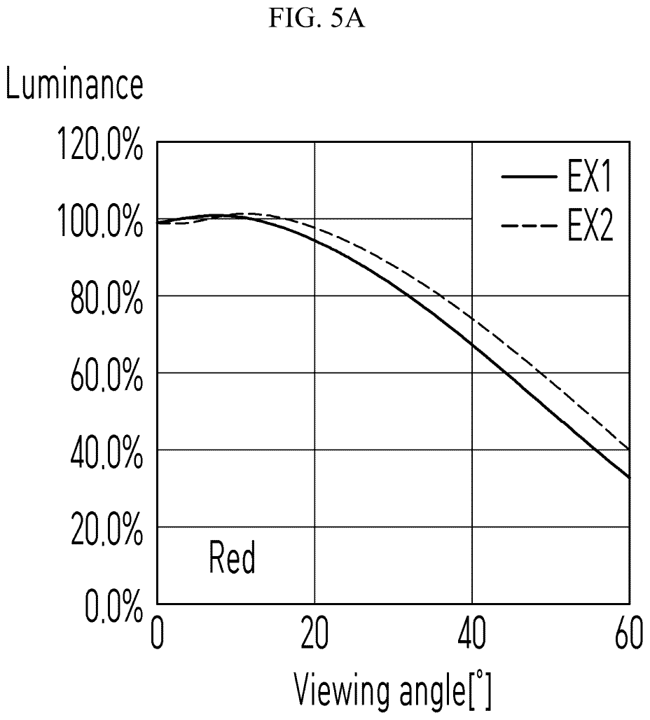

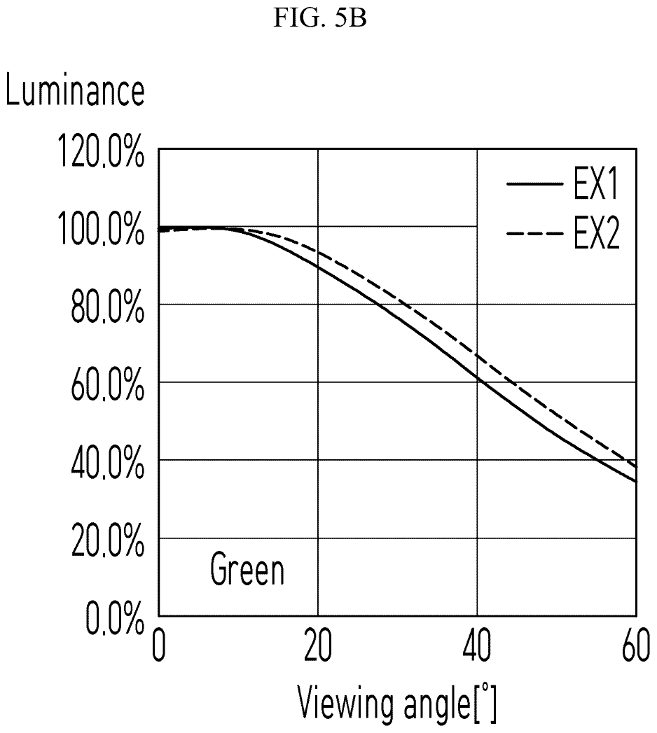

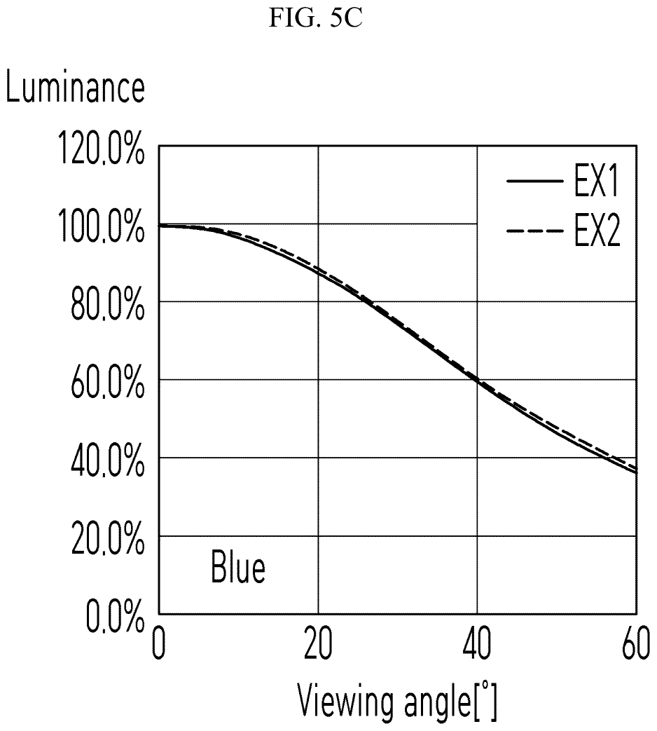

FIG. 4 is a cross-sectional view of a sub-pixel of a light emitting display device according to an embodiment of the present disclosure. FIGS. 5A to 5C are graphs showing luminance according to the viewing angle depending on whether the curved structure shown in FIG. 4 is applied.

As shown in FIG. 4, a sub-pixel SP of a light emitting display device according to an embodiment of the present disclosure includes a single light emitting unit. The light emitting unit is defined by an open region of a bank 155.

A light emitting element ED is provided on a thin-film transistor array 500 formed on a substrate.

The light emitting element includes a pixel electrode 310, an intermediate layer 320 provided on the pixel electrode 310, and a common electrode 330 provided on the intermediate layer 320.

The pixel electrode 310 may include, for example, a reflective electrode formed of a metallic material having high reflectivity or may include a transparent electrode. For example, the pixel electrode 310 may be formed in a single-layer structure of a transparent conductive film such as indium tin oxide (ITO), indium zinc oxide (IZO), tin oxide (TO), or indium tin zinc oxide (ITZO), may be formed in a multilayer structure such as a stacked structure (Ti/Al/Ti) of aluminum (Al) and titanium (Ti), a stacked structure (ITO/Al/ITO) of aluminum (Al) and ITO, an Ag/Pd/Cu (APC) alloy, a stacked structure (ITO/APC/ITO) of an APC alloy and ITO, or a stacked structure (Ag/MoTi) of silver (Ag) and a molybdenum-titanium alloy, or may include a single-layer structure formed of any one material or an alloy of two or more materials selected from among silver (Ag), aluminum (Al), molybdenum (Mo), gold (Au), magnesium (Mg), calcium (Ca), and barium (Ba).

When the pixel electrode 310 is formed as a single layer of a transparent conductive film, a reflective electrode may be included in an underlying curved structure CV that is in contact with the pixel electrode 310, so that light emitted from the light emitting element ED is directed upward.

In a top emission-type light emitting display device, the common electrode 330 may include a transparent electrode or a transflective electrode that is sufficiently thin to allow light to pass through the common electrode 330. The transparent electrode may be formed of, for example, ITO or IZO. The transflective electrode may be formed of any one material or an alloy of two or more materials selected from among, for example, silver (Ag), aluminum (Al), molybdenum (Mo), gold (Au), magnesium (Mg), ytterbium (Yb), and strontium (Sr).

The intermediate layer 320 may include emission layers REML, GEML, and BEML. The intermediate layer 320 may include a first common layer CML1 associated with hole injection and transport, which is disposed between the pixel electrode 310 and the emission layers, and a second common layer CML2 associated with electron transport and injection, which is disposed between the emission layers and the common electrode 330.

The first common layer CML1 may include layers commonly provided over the plurality of sub-pixels SP, for example, a hole injection layer, a hole transport layer, and an electron blocking layer.

The second common layer CML2 may include layers commonly provided over the plurality of sub-pixels SP, for example, a hole blocking layer, an electron transport layer, and an electron injection layer.

Each of the emission layers REML, GEML, and BEML includes one or more hosts and one or more dopants. The red emission layer REML includes a red dopant, the green emission layer GEML includes a green dopant, and the blue emission layer BEML includes a blue dopant. The hosts in each of the emission layers REML, GEML, and BEML transfer energy to the dopants contained in each of the emission layers REML, GEML, and BEML, so that the dopants function to emit light. Each dopant may include a phosphorescent dopant and/or a fluorescent dopant.

In the emission layers REML, GEML, and BEML, when a voltage difference is applied between the pixel electrode 310 and the common electrode 330, holes are transferred through the first common layer CML1, and electrons are transferred through the second common layer CML2. The holes and the electrons meet each other in the emission layers REML, GEML, and BEML to form excitons, and light is emitted as the energy level of the excitons decreases.

When the sub-pixels RSP, GSP, and BSP emit red, green, and blue light, respectively, the respective emission peaks are in the ranges of 605 nm to 650 nm, 505 nm to 590 nm, and 420 nm to 495 nm. The emission layers REML, GEML, and BEML, which emit light of different colors, include different hosts and different dopants in each sub-pixel SP, and the hosts and the dopants have different energy bandgap characteristics and different mobilities.

The red, green, and blue sub-pixels SP require different resonance conditions to exhibit microcavity characteristics at different wavelengths, and accordingly, the distance between the pixel electrode 310 and the common electrode 330 may differ.

In addition, as shown in FIG. 4, the light emitting display device according to the embodiment of the present disclosure includes a curved structure CV provided between the thin-film transistor array 500 and the pixel electrode 310.

The curved structure CV may include a first curved layer 160, which is provided singularly in one light emitting unit, and a second curved layer 170, which includes a plurality of patterns provided on the first curved layer 160 and spaced apart from each other.

The curvature of the first curved layer 160 and the curvature of the second curved layer 170 may be different from each other.

The first curved layer 160 may have a relatively gently curved surface compared to the second curved layer 170. An inclination angle of the first curved layer 160 with respect to the surface of the thin-film transistor array 500 may be less than an inclination angle of the second curved layer 170 with respect to the first curved layer 160.

Based on one light emitting unit, the curved structure CV includes the first curved layer 160, which is formed as a single large lens provided corresponding to the light emitting unit, and the second curved layer 170, which is formed as a plurality of small lenses spaced apart from each other.

Due to the structure in which a large lens and a small lens are vertically stacked, various optical paths are generated in a direction perpendicular to the intermediate layer 320 by a cavity effect, and a light emission effect similar to that in a Lambertian structure is obtained.

The curvature of the second curved layer 170 may be greater than the curvature of the first curved layer 160.

The curvature of the first curved layer 160 in one light emitting unit may be different from the curvatures of the first curved layers in adjacent light emitting units.

In the graph in FIG. 5A, “EX1” represents a first experimental example of measuring a luminance variation according to a viewing angle when observing a red light emitting unit without the curved structure, and “EX2” represents a second experimental example of measuring a luminance variation according to a viewing angle when observing a red light emitting unit including the curved structure shown in FIG. 4. In the experimental examples, an internal angle of the first curved layer 160 with respect to the thin-film transistor array 500 is set to 5°.

It can be confirmed that, across the entire viewing angle range, the luminance of red is improved in the second experimental example EX2, in which the curved structure is employed, compared to the first experimental example EX1.

In the graph in FIG. 5B, “EX1” represents a first experimental example of measuring a luminance variation according to a viewing angle when observing a green light emitting unit without the curved structure, and “EX2” represents a second experimental example of measuring a luminance variation according to a viewing angle when observing a green light emitting unit including the curved structure shown in FIG. 4. In the experimental examples, an internal angle of the first curved layer 160 with respect to the thin-film transistor array 500 is set to 5°.

It can be confirmed that, across the entire viewing angle range, the luminance of green is improved in the second experimental example EX2, in which the curved structure is employed, compared to the first experimental example EX1.

In the graph in FIG. 5C, “EX1” represents a first experimental example of measuring a luminance variation according to a viewing angle when observing a blue light emitting unit without the curved structure, and “EX2” represents a second experimental example of measuring a luminance variation according to a viewing angle when observing a blue light emitting unit including the curved structure shown in FIG. 4. In the experimental examples, an internal angle of the first curved layer 160 with respect to the thin-film transistor array 500 is set to 3°.

It can be confirmed that, across the entire viewing angle range, the luminance of blue is improved in the second experimental example EX2, in which the curved structure is employed, compared to the first experimental example EX1.

As described above, it can be confirmed that the luminance is improved across the entire viewing angle when the two-layer curved structure, in which two layers having different curvatures are vertically stacked, is applied to each of the red light emitting unit, the green light emitting unit, and the blue light emitting unit.

Hereinafter, the structure of a light emitting display device, in which the two-layer curved structure shown in FIG. 4 is applied differently to light emitting units of different colors, will be described.

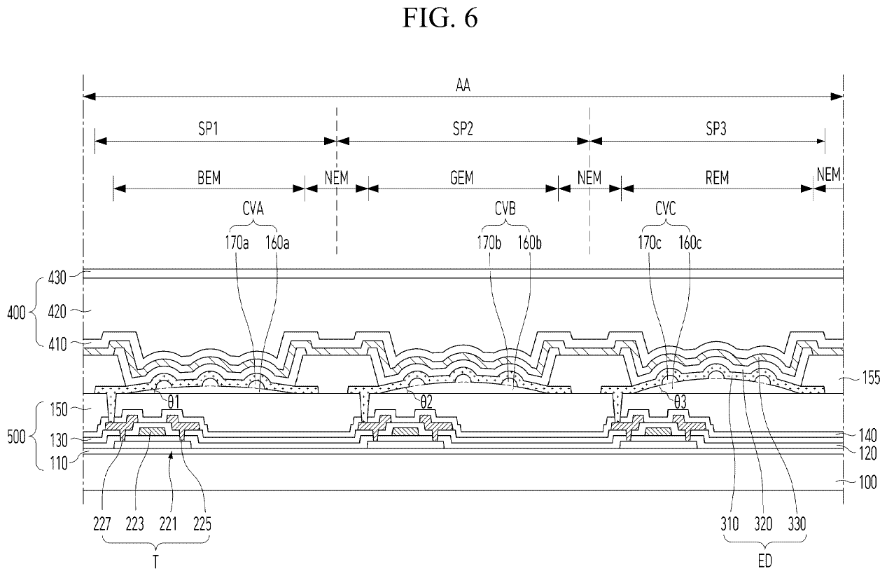

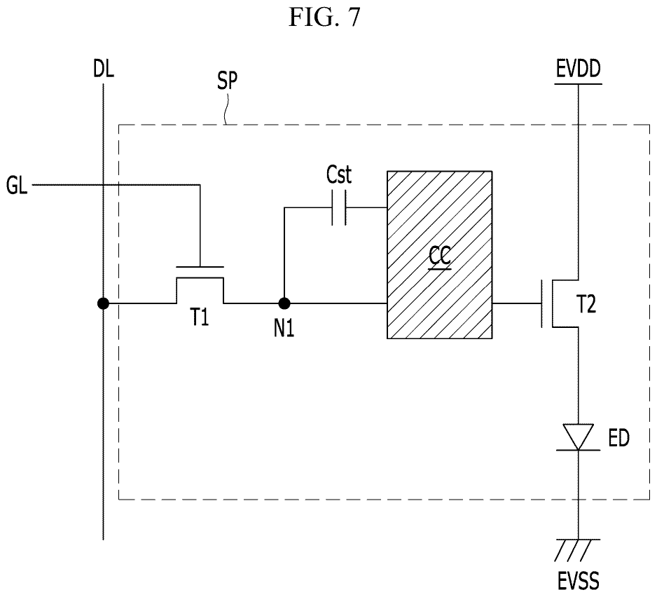

FIG. 6 is a cross-sectional view of the light emitting display device according to the embodiment of the present disclosure, and FIG. 7 is a diagram showing a pixel circuit corresponding to the sub-pixel shown in FIG. 6 according to an example.

As shown in FIG. 6, a light emitting display device according to an embodiment of the present disclosure includes a substrate 100, which includes a first light emitting unit BEM, a second light emitting unit GEM, and a third light emitting unit REM, and a light emitting element ED, which is provided on the substrate 100 and includes a pixel electrode 310 disposed corresponding to each of the first to third light emitting units BEM, GEM, and REM, an intermediate layer 320 disposed on the pixel electrode 310, and a common electrode 330 disposed on the intermediate layer 320.

In addition, a curved structure CVA provided at the first light emitting unit BEM includes a first curved layer 160a disposed between the substrate 100 and the pixel electrode 310 and a second curved layer 170a including a plurality of patterns disposed on the first curved layer 160a and spaced apart from each other. Similar to the curved structure CVA, a curved structure CVB provided at the second light emitting unit GEM includes a first curved layer 160b and a second curved layer 170b, and a curved structure CVC provided at the third light emitting unit REM includes a first curved layer 160c and a second curved layer 170c.

The first curved layers 160a, 160b, and 160c provided at the light emitting units BEM, GEM, and REM are formed to have different internal angles θ1, θ2, and θ3 with respect to the surface of a planarization layer 150.

In the illustrated example, the internal angles θ1, θ2, and θ3 of the first curved layers 160a, 160b, and 160c with respect to the surface of the planarization layer 150 gradually increase from the blue light emitting unit BEM to the red light emitting unit REM via the green light emitting unit GEM. However, the present disclosure is not limited thereto. That is, the internal angles θ1, θ2, and θ3 of the first curved layers 160a, 160b, and 160c with respect to the surface of the planarization layer 150 in the blue, green, and red light emitting units BEM, GEM, and REM may be different from each other, and the order in which the internal angles θ1, θ2, and θ3 increase may differ from that in the illustrated example.

Alternatively, the internal angles of the first curved layers in two light emitting units among the blue, green, and red light emitting units BEM, GEM, and REM may be set to the same value, and the internal angle of the first curved layer in the remaining light emitting unit may be set to another value. The curvature of the first curved layer in any one of the blue, green, and red light emitting units BEM, GEM, and REM may differ from the curvatures of the first curved layers in the remaining light emitting units.

As in the above-described experimental examples, the internal angles of the first curved layers in the red light emitting unit REM and the green light emitting unit GEM may be set to the same value, and the internal angle of the first curved layer in the blue light emitting unit BEM may be set to a smaller value.

Alternatively, for example, among the blue, green, and red light emitting units, the curvature of the first curved layer in the green light emitting unit may be set to the largest value. When the curvature of the first curved layer in the green light emitting unit is the greatest, not only the luminance of green but also the overall luminance characteristic of white may be significantly improved.

Alternatively, among the blue, green, and red light emitting units, the curvature of the first curved layer in the red light emitting unit or the curvature of the first curved layer in the blue light emitting unit may be set to the largest value.

In some cases, the first curved layer may be employed in only one or two of the blue, green, and red light emitting units, while not being employed in the remaining two or one of the light emitting units.

As described above, the light emitting display device according to the embodiment of the present disclosure is characterized in that the structures of the first and second curved layers employed in the red, green, and blue light emitting units differ from each other. The structure of the first and second curved layers may vary depending on customer requirements, and specific effects thereof will be described later in connection with experimental results.

Each of the second curved layers 170a, 170b, and 170c is provided on an upper surface of a corresponding one of the first curved layers 160a, 160b, and 160c, and includes a plurality of patterns having a shape similar to a hemisphere and spaced apart from each other.

In the curved structures CVA, CVB, and CVC of the light emitting units BEM, GEM, and REM, the first curved layers 160a, 160b, and 160c having a large lens shape and the second curved layers 170a, 170b, and 170c having a small lens shape allow light emitted from the light emitting elements ED to propagate radially, thereby improving not only the front luminance but also the overall luminance across the entire viewing angle range.

Hereinafter, components around the curved structures CVA, CVB, and CVC will be described.

The substrate 100 functions to support and protect components disposed thereon. The substrate 100 may have transparent and flexible properties. For example, the substrate 100 may be formed of a glass or plastic material.

The substrate 100 may be formed in a multilayer structure. For example, the substrate 100 may be configured such that an interlayer inorganic film is disposed between different flexible substrates.

A thin-film transistor array 500 is provided on the substrate 100.

For example, as shown in FIG. 7, the thin-film transistor array 500 may include, in correspondence with each sub-pixel SP, a first transistor T1, a second transistor T2, a storage capacitor Cst, a compensation circuit CC, and a light emitting element ED.

As one example, the first transistor T1 may be a switching transistor, and the second transistor T2 may be a driving transistor.

A first electrode (e.g., a drain electrode) of the first transistor T1 is electrically connected to a data line DL, and a second electrode (e.g., a source electrode) of the first transistor T1 is electrically connected to a first node N1. A gate electrode of the first transistor T1 is electrically connected to a gate line GL. The first transistor T1 transfers a data signal supplied through the data line DL to the first node N1 in response to a scan signal supplied through the gate line GL.

The storage capacitor Cst is electrically connected to the first node N1 and charges the voltage applied to the first node N1.

A first electrode (e.g., a drain electrode) of the second transistor T2 receives a high-potential driving voltage EVDD through a high-potential voltage line VDDL, and a second electrode (e.g., a source electrode) of the second transistor T2 is electrically connected to a first electrode (e.g., an anode AND) of the light emitting element ED. The second transistor T2 may control an amount of driving current flowing through the light emitting element ED in response to the voltage applied to the gate electrode.

A semiconductor layer of the first transistor T1 and/or the second transistor T2 may include silicon such as amorphous silicon (a-Si), polycrystalline silicon (poly-Si), or low-temperature polycrystalline silicon (LTPS) or may include an oxide such as indium gallium zinc oxide (IGZO). However, the present disclosure is not limited thereto. At least one of the first transistor T1 or the second transistor T2 may include an oxide semiconductor layer, and thus may enable relatively low-temperature processing compared to other materials and may exhibit high mobility while maintaining amorphous characteristics.

The light emitting element ED outputs light corresponding to the driving current. The light emitting element ED may output light corresponding to any one of red, green, blue, and white in each sub-pixel SP.

The light emitting element ED may include a pixel electrode 310, an intermediate layer 320 disposed on the pixel electrode 310, and a common electrode 330 that receives a common voltage. The intermediate layer 320 may be configured such that a hole injection layer, a hole transport layer, an emission layer, an electron transport layer, and an electron injection layer are stacked. Thereamong, the hole injection layer, the hole transport layer, the electron transport layer, and the electron injection layer may be commonly provided over the form of common layers in the sub-pixels, and the emission layer may be individually disposed in each sub-pixel SP. In some cases, the intermediate layer 320 may have a tandem structure that includes a plurality of units, in each of which a hole transport common layer, at least one emission layer, and an electron transport common layer are stacked, and a charge generation layer interposed between adjacent units. When the intermediate layer 320 having the tandem structure is applied to the light emitting element ED, a color filter may be provided on an encapsulation layer 400 through which light is emitted, so that color representation is performed in each sub-pixel.

The common electrode of the light emitting element ED receives a low-potential voltage EVSS or a ground voltage. A low-potential voltage line VSSL may be disposed and included in the non-active area NA. In some cases, to prevent non-uniformity of the low-potential voltage EVSS generated in the active area AA, the low-potential voltage line VSSL may also be disposed in the active area AA. The low-potential voltage EVSS is also referred to as a common voltage.

The compensation circuit CC may be provided at the sub-pixel SP in order to compensate for the threshold voltage of the second transistor T2. The compensation circuit CC may include one or more transistors. The compensation circuit CC may include one or more transistors and capacitors. The compensation circuit CC may be configured in various forms depending on the compensation method. The sub-pixel including the compensation circuit CC may include various circuit structures, such as 3T1C, 4T2C, 5T2C, 6T1C, 6T2C, 7T1C, or 7T2C, with different numbers of transistors and/or capacitors.

The thin-film transistor array 500 on the substrate 100 may include a transistor T and a plurality of insulating layers 110, 120, 130, 140, and 150 provided between the substrate 100 and the pixel electrode 310.

The transistor T may include an active layer 221, a gate electrode 223 overlapping the active layer 221 with a second insulating layer 120 interposed therebetween, and first and second source/drain electrodes 225 and 227 connected to respective sides of the active layer 221. The active layer 221 may include a semiconductor material. The semiconductor material may be a silicon-based semiconductor material or an oxide semiconductor material.

A light-shielding pattern may be further provided between the substrate 100 and the transistor T. The light-shielding pattern may block light from a region below the substrate 100 from reaching the transistor TFT, thereby preventing abnormal operation such as generation of photocurrent.

A first insulating layer 110 may be provided between the substrate 100 and the active layer 221. The first insulating layer 110 may function as a buffer layer. The first insulating layer 110 may function to prevent impurities contained in the substrate 100 from being transferred to the active layer 221 and to planarize the surface on which the active layer 221 is formed. The first insulating layer 110 may cover the light-shielding pattern. The first insulating layer 110 may protect structures on the substrate 100 that are vulnerable to moisture permeation by blocking moisture permeating through the substrate 100 and may planarize the surface of the substrate 100.

In some cases, one or more insulating layers may be provided between the light-shielding pattern and the substrate 100 to prevent impurities from entering the overlying array structure from the substrate 100 and to protect the array structure on the substrate 100.

A second insulating layer 120 that functions as a gate insulating layer may be provided between the active layer 221 and the gate electrode 223.

A third insulating layer 130 may be provided between the gate electrode 223 and the first and second source/drain electrodes 225 and 227 to provide interlayer insulation. The third insulating layer 130 may be provided singularly or in plural.

The electrodes of the transistor TFT and the electrodes of the storage capacitor Cst may be disposed on the same layer.

Each of the light-shielding pattern, the gate electrode 223, the first and second source/drain electrodes 225 and 227, and the first and second storage electrodes may include a metal selected from the group consisting of aluminum (Al), titanium (Ti), copper (Cu), chromium (Cr), molybdenum (Mo), and tungsten (W).

A plurality of transistors TFT may be provided at the sub-pixel SP (SP1, SP2, or SP3). Some of the plurality of transistors TFT may function as switching transistors, and others may function as driving transistors. To implement different functions, the stacking structure of the switching transistor and the driving transistor may be varied, or the width and/or the length of the active layer channel may be varied.

A fourth insulating layer 140 and a fifth insulating layer 150 may be disposed to cover the transistor T.

Each of the first to fourth insulating layers 110, 120, 130, and 140 may include an inorganic insulating film, for example, a silicon oxide (SiOx) film, a silicon nitride (SiNx) film, or a multilayer film formed by stacking the same.

The fifth insulating layer 150 serves to planarize the surface on which the curved structure CV is disposed. Thus, the fifth insulating layer 150 is referred to as a planarization layer.

The fifth insulating layer 150 may include an organic material. The organic material may include at least one material selected from the group consisting of acrylic resin, phenolic resin, polyimide resin, unsaturated polyester resin, polyamide resin, benzocyclobutene, polyphenylene resin, and polyphenylene sulfide resin.

In addition to the first to fifth insulating layers 110, 120, 130, 140, and 150, organic or inorganic layers having various functions may additionally be provided.

The curved structures CVA, CVB, and CVC, which are provided on the fifth insulating layer 150, may be formed by patterning an organic material identical to the material of the fifth insulating layer 150.

Alternatively, the curved structures CVA, CVB, and CVC may be formed by processing a metal. In this case, the curved structures CVA, CVB, and CVC are formed of a material different from that of the underlying fifth insulating layer 150. Therefore, the curved structures CVA, CVB, and CVC may have selective etchability in the patterning processes of the first curved layers 160a, 160b, and 160c and the second curved layers 170a, 170b, and 170c, thereby allowing patterning without damage to the fifth insulating layer 150.

In some cases, the curved structures CVA, CVB, and CVC may include a reflective electrode material. When the curved structures CVA, CVB, and CVC include a reflective electrode material, the pixel electrode 310 connected to the upper portions thereof may include a transparent electrode material.

When the curved structures CVA, CVB, and CVC include a reflective electrode material, reflection and resonance may be repeatedly generated between the upper surfaces of the curved structures CVA, CVB, and CVC and the common electrode 330 in the light emitting elements ED of the light emitting units BEM, GEM, and REM, thereby enhancing the microcavity effect.

In the light emitting display device shown in FIG. 6, the first curved structure CVA provided at the blue light emitting unit BEM may include a first curved layer 160a having a first internal angle θ1 with respect to the surface of the fifth insulating layer 150 and a second curved layer 170a including a plurality of patterns provided on the surface of the first curved layer 160a and spaced apart from each other. The first internal angle θ1 is the smallest among the internal angles of the curved structures provided at the blue, green, and red light emitting units BEM, GEM, and REM. The second curved structure CVB provided at the green light emitting unit GEM may include a first curved layer 160b having a second internal angle θ2 with respect to the surface of the fifth insulating layer 150 and a second curved layer 170b including a plurality of patterns provided on the surface of the first curved layer 160b and spaced apart from each other. The third curved structure CVC provided at the red light emitting unit REM may include a first curved layer 160c having a third internal angle θ3 with respect to the surface of the fifth insulating layer 150 and a second curved layer 170c including a plurality of patterns provided on the surface of the first curved layer 160c and spaced apart from each other.

As such, in the light emitting display device shown in FIG. 6, the inclination of the first curved layers 160a, 160b, and 160c may gradually increase in the order of the blue, green, and red light emitting units. However, this is merely one example. The difference in inclination between the first curved layers 160a, 160b, and 160c may vary depending on the desired viewing angle characteristics and the priority of color accuracy in the light emitting display device.

The light emitting element ED of each light emitting unit includes a pixel electrode 310, an intermediate layer 320, and a common electrode 330.

The pixel electrode 310 may include a metallic material having high reflectivity. For example, the pixel electrode 310 may be formed in a multilayer structure such as a stacked structure (Ti/Al/Ti) of aluminum (Al) and titanium (Ti), a stacked structure (ITO/Al/ITO) of aluminum (Al) and ITO, an Ag/Pd/Cu (APC) alloy, a stacked structure (ITO/APC/ITO) of an APC alloy and ITO, or a stacked structure (Ag/MoTi) of silver (Ag) and a molybdenum-titanium alloy, or may include a single-layer structure formed of any one material or an alloy of two or more materials selected from among silver (Ag), aluminum (Al), molybdenum (Mo), gold (Au), magnesium (Mg), calcium (Ca), and barium (Ba). The pixel electrode 310 may be referred to as a reflective electrode.

The intermediate layer 320 may include a hole injection layer, a hole transport layer, an organic emission layer, an electron transport layer, and an electron injection layer.

An edge of the pixel electrode 310 may overlap the bank 155. A region of the pixel electrode 310 exposed from the bank 155 may be a light emitting unit.

When different voltages are applied to the pixel electrode 310 and the common electrode 330, holes move to the organic emission layer through the hole injection layer and the hole transport layer, and electrons move to the organic emission layer through the electron injection layer and the electron transport layer. In the organic emission layer, the holes and the electrons recombine to form excitons, and light emission occurs as the excitons transition from an excited state to a ground state.

The intermediate layer 320 may include at least one of a red emission layer configured to emit red light, a green emission layer configured to emit green light, or a blue emission layer configured to emit blue light. The red emission layer, the green emission layer, and the blue emission layer may be disposed on the pixel electrode 310 in respective sub-pixels SP. For example, the red emission layer may be patterned in the red sub-pixel, the green emission layer may be patterned in the green sub-pixel, and the blue emission layer may be patterned in the blue sub-pixel. However, the present disclosure is not limited thereto. At least two organic emission layers among the red emission layer, the green emission layer, and the blue emission layer may be disposed in a stacked structure in one sub-pixel SP.

Each layer of the intermediate layer 320 may be commonly provided across the entire active area AA. In some cases, any one layer of the intermediate layer 320 may be selectively provided at the light emitting units BEM, REM, and GEM. The intermediate layer 320 of the light emitting element ED may have a tandem structure that includes a plurality of stacks, each of which includes an emission layer, a hole transport-related common layer provided under the emission layer, and an electron transport-related common layer provided under the emission layer, and a charge generation layer interposed between adjacent stacks. In the tandem structure, each layer of the intermediate layer 320, which includes the charge generation layer, may be a common layer disposed over the entire active area AA.

The intermediate layer 320 may be a white emission layer configured to emit white light. In this case, the organic emission layer of the intermediate layer 320 may be a common layer that is commonly disposed in the sub-pixels SP, rather than being patterned in each sub-pixel SP.

The common electrode 330 may be a common layer that is commonly disposed in the sub-pixels SP to apply the same voltage. To this end, the common electrode 330 may extend from the active area AA to a portion of the non-active area NA.

The common electrode 330 may be a light-transmissive electrode. The common electrode 330 may include a transparent conductive material (TCO) such as indium tin oxide (ITO) or indium zinc oxide (IZO), which is capable of transmitting light, or a semi-transmissive conductive material such as magnesium (Mg), silver (Ag), or an alloy of magnesium (Mg) and silver (Ag). When the common electrode 330 includes a semi-transmissive conductive material, the light emitting efficiency may be improved by the microcavity effect. When the common electrode 330 includes a semi-transmissive conductive material, the thickness of the common electrode 330 may be sufficiently thin to allow light transmission. For example, the thickness of the common electrode 330 may be 200 Å or less.

The pixel electrode 310 or the curved structures CVA, CVB, and CVC may include a reflective electrode in order to prevent light generated in the intermediate layer 320 from being transmitted to light-shielding components located below the pixel electrode 310 or the curved structures CVA, CVB, and CVC. The light generated in the intermediate layer 320 may resonate between the common electrode 330 and the pixel electrode 310, and may ultimately be emitted upward through the common electrode 330. Since the pixel electrode 310 or the curved structures CVA, CVB, and CVC include a reflective component, light emitted from the light emitting element ED may be extracted through the light emitting units BEM, GEM, and REM, even when the pixel electrode 310 or the curved structures CVA, CVB, and CVC are disposed to overlap the wiring or the transistor T.

The pixel electrode 310, the intermediate layer 320, and the common electrode 330 may be formed along the corrugated surfaces of the curved structures CVA, CVB, and CVC, and may control the directional emission of light from the light emitting units BEM, GEM, and REM.

An encapsulation layer 400 is provided on the light emitting element ED. In one example, the encapsulation layer 400 may have a structure in which inorganic encapsulation layers 410 and 430 and an organic encapsulation layer 420 are alternately stacked.

In some cases, the encapsulation layer 400 may be implemented in a single-layer structure.

It may be advantageous that the uppermost layer and the lowermost layer of the encapsulation layer 400 are the inorganic encapsulation layers 430 and 410 to prevent ingress of external moisture or air.

The encapsulation layer 400 planarizes surface irregularities of the light emitting element ED.

In some cases, a touch sensor or a color filter structure may be additionally disposed on the encapsulation layer 400.

Hereinafter, luminance characteristics will be described based on a third experimental example EX3 in which the curved structure is not employed, a fourth experimental example EX4 in which a plurality of small lenses is employed in the light emitting unit, as shown in FIG. 2, a fifth experimental example EX5 in which a single lens of the first curved layer shown in FIG. 4 is employed, and a sixth experimental example EX6 in which both the first and second curved layers shown in FIG. 4 are employed.

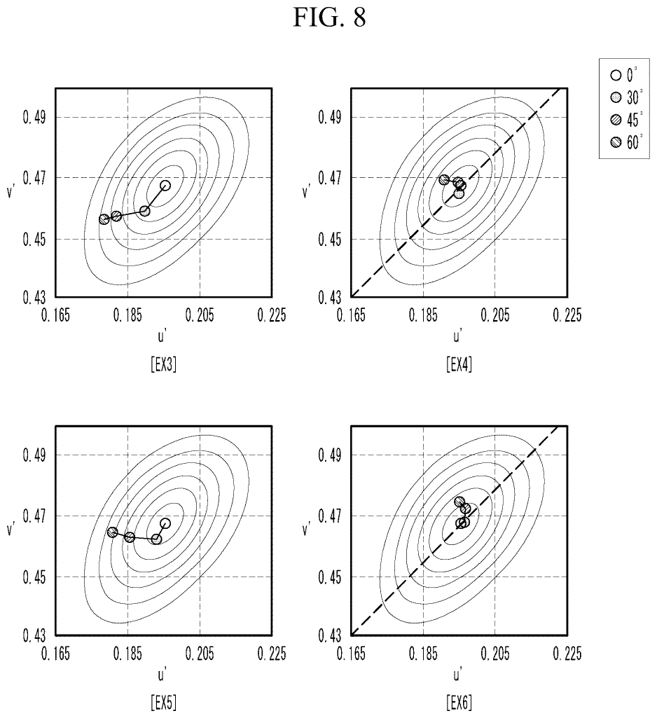

FIG. 8 illustrates graphs showing the viewing angle characteristics of the third to sixth experimental examples.

In the experiments shown in Tables 2 and 3 and FIG. 8, the internal angle θ3 formed between the surface of the planarization layer and the first curved layer in the red light emitting unit was set to 5°, the internal angle θ2 formed between the surface of the planarization layer and the first curved layer in the green light emitting unit was set to 5°, and the internal angle θ1 formed between the surface of the planarization layer and the first curved layer in the blue light emitting unit was set to 3°. The results in Tables 2 and 3 represent the luminance characteristics when all the red, green, and blue light emitting units were turned on to implement white.

TABLE 2

Luminance (%)

| Viewing | | EX4 | EX5 | EX6 |
|---|---|---|---|---|
| Angle | EX3 | (Small | (Large | (Small Lens + |
| (°) | (Flat) | Lens) | Lens) | Large Lens) |
| 30 | 76.2 | 78.2 | 83.7 | 84.8 |
| 45 | 50.0 | 55.4 | 58.6 | 62.9 |
| 60 | 26.7 | 34.7 | 33.3 | 40.7 |

Referring to Table 2, it can be seen that, compared to the third experimental example EX3, the luminance is improved at various viewing angles when at least a portion of the curved structure is employed.

Compared to the fourth experimental example EX4, in which a plurality of small lenses is employed, the fifth experimental example EX5, in which a large lens is employed, exhibits improved luminance characteristics at viewing angles of 30° and 45°. However, at a viewing angle of 60°, the fourth experimental example EX4 employing a plurality of small lenses exhibits improved luminance characteristics compared to the fifth experimental example EX5.

Referring to FIG. 8, in the fifth experimental example EX5, when the viewing angle changes, the range of color coordinate shift according to the change in viewing angle is small, considering the white color coordinates at the front. However, considering the dispersion characteristics, the color tends to appear reddish.

The sixth experimental example EX6, which corresponds to the embodiment of the present disclosure shown in FIG. 6, exhibits improved luminance characteristics at each viewing angle compared to the third to fifth experimental examples EX3 to EX5.

In addition, as shown in FIG. 8, in the sixth experimental example EX6, the variation in perceived color with changes in viewing angle is smaller than that in the third to fifth experimental examples EX3 to EX5. Furthermore, in the sixth experimental example EX6, as the viewing angle changes, the color shift moves toward the green wavelength region, which may reduce the user's perception of color deviation compared to the fifth experimental example EX5.

TABLE 3

| Viewing | Luminance Variation (%) | | |
|---|---|---|---|
| Angle Change | EX3 | EX6 | EX3 − EX6 |
| 30° → 45° | 26.20 | 21.90 | 4.3 |
| 40° → 60° | 23.30 | 22.20 | 1.1 |

Referring to Table 3, it can be seen that the sixth experimental example EX6, in which the curved structure according to the embodiment of the present disclosure is employed, exhibits smaller luminance variation according to changes in viewing angle than the third experimental example EX3, in which the curved structure is not employed. This indicates that luminance deviation perceived by a user at different viewing angles is smaller in the sixth experimental example EX6 than in the third experimental example EX3.

Accordingly, it can be confirmed based on the above-described experiments that the light emission characteristic approaches a Lambertian light emission characteristic due to luminance improvement in each light emitting unit resulting from the application of the embodiment of the present disclosure.

In addition, in the sixth experimental example, the luminance characteristics increase by 12.9% at a viewing angle of 45°, and the perceived color exhibits a greenish tendency.

In addition, according to the embodiment of the present disclosure, luminance variation according to changes in viewing angle is improved. It can be confirmed that luminance variation is improved by 4.3% when the viewing angle changes from 30° to 45°.

Hereinafter, luminance characteristics will be described based on a seventh experimental example EX7 in which the curved structure is not employed, an eighth experimental example EX8 in which a plurality of small lenses is employed in the light emitting unit, as shown in FIG. 2, a ninth experimental example EX9 in which a single lens of the first curved layer shown in FIG. 4 is employed, and a tenth experimental example EX10 in which both the first and second curved layers shown in FIG. 4 are employed. The internal angles of the first curved layers in the respective light emitting units in the seventh to tenth experimental examples EX7 to EX10 are different from those in the above-described third to sixth experimental examples. In the experiments shown in Tables 4 and 5, the internal angle θ3 formed between the surface of the planarization layer and the first curved layer in the red light emitting unit was set to 4°, the internal angle θ2 formed between the surface of the planarization layer and the first curved layer in the green light emitting unit was set to 3°, and the internal angle θ1 formed between the surface of the planarization layer and the first curved layer in the blue light emitting unit was set to 1°. The results in Tables 4 and 5 represent the luminance characteristics when all the red, green, and blue light emitting units were turned on to implement white.

TABLE 4

| | | | | | EX10 |
|---|---|---|---|---|---|
| | | | | | (Small |
| | | | EX8 | EX9 | Lens + |
| | | EX7 | (Small | (Large | Large |
| | | (Flat) | Lens) | Lens) | Lens) |
| Color Perception (JND | | 14 | 6 | 13 | 6 |
| @Max) | | | | | |
| Color Shift Direction | | Bluish | Reddish → | Reddish → | Greenish |
| | | | Cyanish | Cyanish | |
| Lumi- | Viewing | 76.2 | 78.2 | 81.1 | 82.4 |
| nance | Angle 30° | | | | |
| (%) | Viewing | 50.0 | 55.4 | 55.4 | 60.1 |
| | Angle 45° | | | | |
| | Viewing | 26.7 | 34.7 | 30.8 | 38.5 |
| | Angle 60° | | | | |

TABLE 5

| Viewing | Luminance Variation (%) | | |
|---|---|---|---|
| Angle Change | EX7 | EX10 | EX7 − EX10 |
| 30° → 45° | 26.20 | 22.30 | 3.9 |
| 40° → 60° | 23.30 | 21.60 | 1.7 |

Referring to the experimental results in Tables 4 and 5, it can be confirmed that the light emission characteristic approaches a Lambertian light emission characteristic due to luminance improvement in each light emitting unit resulting from the application of the embodiment of the present disclosure. It can also be confirmed that luminance improvement of 5% or more is achieved across the entire viewing angle range.

In addition, the light emitting display device according to the embodiment of the present disclosure may achieve luminance improvement without color coordinate shift, thereby optimizing color appearance and color perception and enabling stable and accurate color reproduction.

Table 6 below presents the results of evaluating color perception, color shift direction, and luminance characteristics with respect to viewing angle when the internal angle θ of the first curved layer in the red light emitting unit is set to 0° and the internal angles θ of the first curved layers in the green and blue light emitting units are set to 0° or 5°.

TABLE 6

| Large | R | 0 | 0 | 0 | 0 |
|---|---|---|---|---|---|
| Lens | G | 0 | 5 | 0 | 5 |
| θ(°) | B | 0 | 0 | 5 | 5 |
| Color Perception | | 7 | 17 | 9 | 14 |
| (JND @Max) | | | | | |
| Color Shift Direction | | Reddish → | Greenish | Magenta | Bluish → |
| | | Cyanish | | | Cyanish |
| Lumi- | Viewing | 78.2 | 83.2 | 78.8 | 83.7 |
| nance | Angle 30° | | | | |
| (%) | Viewing | 55.4 | 60.8 | 55.9 | 61.4 |
| | Angle 45° | | | | |
| | Viewing | 34.7 | 38.8 | 35.0 | 39.1 |
| | Angle 60° | | | | |

Table 7 below presents the results of evaluating color perception, color shift direction, and luminance characteristics with respect to viewing angle when the internal angle θ of the first curved layer in the red light emitting unit is set to 5° and the internal angles θ of the first curved layers in the green and blue light emitting units are set to 0° or 5°.

TABLE 7

| Large | R | 5 | 5 | 5 | 5 |
|---|---|---|---|---|---|
| Lens | G | 0 | 5 | 0 | 5 |
| θ(°) | B | 0 | 0 | 5 | 5 |
| Color Perception | | 8 | 11 | 12 | 4 |
| (JND @Max) | | | | | |
| Color Shift Direction | | Reddish → | Yellowish | Reddish | Reddish → |
| | | Yellowish | | | Greenish |
| Lumi- | Viewing | 79.6 | 84.5 | 80.1 | 85.0 |
| nance | Angle 30° | | | | |
| (%) | Viewing | 57.1 | 62.5 | 57.7 | 63.1 |
| | Angle 45° | | | | |
| | Viewing | 36.4 | 40.5 | 36.8 | 40.9 |
| | Angle 60° | | | | |

The experimental results shown in Tables 6 and 7 above demonstrate that the curvature of the first curved layer may be applied differently to the light emitting display device depending on the desired color perception.

It can be seen that, when the curvature of the first curved layer is applied only to the red light emitting unit, reddish or yellowish color characteristics are implemented and luminance is slightly improved with respect to viewing angle change.

It can be seen that, when the curvature of the first curved layer is applied only to the green light emitting unit, the luminance characteristics are most significantly influenced, resulting in luminance improvement of 5% or more at a viewing angle of 45°.

When the curvature of the first curved layer is applied only to the blue light emitting unit, magenta or bluish color characteristics may be implemented.

When the curvature of the first curved layer is applied to both the green and blue light emitting units, bluish or cyanish color characteristics may be implemented, and the luminance characteristics may also be greatly improved.

When the curvature of the first curved layer is applied to both the red and green light emitting units, yellowish color characteristics may be implemented, and luminance improvement may also be achieved.

When the curvature of the first curved layer is applied to both the red and blue light emitting units, reddish color characteristics may be implemented, and slight luminance improvement may also be achieved.

Referring to Tables 6 and 7 above, it can be seen that luminance is greatly improved when the curvature of the first curved layer is applied to the green light emitting unit.

The above experimental results demonstrate that desired color characteristics may be implemented by selectively applying various curvatures.

As is apparent from the above description, the light emitting display device according to the embodiment of the present disclosure may improve light emitting efficiency in a manner similar to Lambertian characteristics by applying a curved structure under a pixel electrode.

The light emitting display device according to the embodiment of the present disclosure may improve not only light emitting efficiency but also luminance characteristics according to changes in viewing angle by providing a curved structure including two layers stacked vertically at each of light emitting units.

The light emitting display device according to the embodiment of the present disclosure may vary luminance compensation for each color by setting the curvatures of first curved layers provided at respective light emitting units to be different from each other. In addition, the multi-layered curved structure may meet customer requirements for implementing diverse color characteristics.

The light emitting display device according to the embodiment of the present disclosure may prevent or reduce luminance deviation for each color depending on viewing angle.

The light emitting display device according to the embodiment of the present disclosure may implement Environmental/Social/Governance (ESG) by improving light emitting efficiency and viewing angle-luminance characteristics without adding processes.

A light emitting display device according to one embodiment of the present disclosure may comprise a substrate comprising a plurality of light emitting units, a light emitting element on the substrate, the light emitting element comprising a pixel electrode corresponding to one of the plurality of light emitting units, an intermediate layer on the pixel electrode, and a common electrode on the intermediate layer and a curved structure between the substrate and the light emitting element.

The curved structure may comprise a first curved layer at a corresponding light emitting unit and a second curved layer comprising a plurality of patterns disposed on the first curved layer and spaced apart from each other.

In a light emitting display device according to one embodiment of the present disclosure, the first curved layer at one of the plurality of light emitting units may have a curvature different from curvatures of first curved layers at adjacent light emitting units.

In a light emitting display device according to one embodiment of the present disclosure, the second curved layer may have a curvature greater than a curvature of the first curved layer.

In a light emitting display device according to one embodiment of the present disclosure, the plurality of light emitting units may comprise a first light emitting unit configured to emit light of a first color, a second light emitting unit configured to emit light of a second color having a longer wavelength than the first color and a third light emitting unit configured to emit light of a third color having a shorter wavelength than the first color.

The first curved layer at the first light emitting unit, the first curved layer at the second light emitting unit, and the first curved layer at the third light emitting unit may have different curvatures.

In a light emitting display device according to one embodiment of the present disclosure, the plurality of light emitting units may comprise a first light emitting unit configured to emit light of a first color, a second light emitting unit configured to emit light of a second color having a longer wavelength than the first color and a third light emitting unit configured to emit light of a third color having a longer wavelength than the second color and wherein the first curved layer at one of the first to third light emitting units has a curvature different from curvatures of first curved layers at remaining ones of the first to third light emitting units.

In a light emitting display device according to one embodiment of the present disclosure, the plurality of light emitting units may comprise a first light emitting unit configured to emit light of a first color, a second light emitting unit configured to emit light of a second color having a longer wavelength than the first color, and a third light emitting unit configured to emit light of a third color having a longer wavelength than the second color. The first curved layer at the third light emitting unit may have a largest curvature.

In a light emitting display device according to one embodiment of the present disclosure, the plurality of light emitting units may comprise a first light emitting unit configured to emit light of a first color, a second light emitting unit configured to emit light of a second color having a longer wavelength than the first color and a third light emitting unit configured to emit light of a third color having a longer wavelength than the first color. The first curved layer at the second light emitting unit may have a largest curvature.

In a light emitting display device according to one embodiment of the present disclosure, the first curved layer at the first light emitting unit, the first curved layer at the second light emitting unit, and the first curved layer at the third light emitting unit may comprise the same material.

In a light emitting display device according to one embodiment of the present disclosure, the second curved layer at the first light emitting unit, the second curved layer at the second light emitting unit, and the second curved layer at the third light emitting unit may have the same curvature.

In a light emitting display device according to one embodiment of the present disclosure, the second curved layer may have a curvature greater than a maximum curvature of the different curvatures.

In a light emitting display device according to one embodiment of the present disclosure, the first curved layer and the second curved layer may comprise an organic material.

In a light emitting display device according to one embodiment of the present disclosure, the pixel electrode may be in contact with the second curved layer and a portion of the first curved layer not covered by the second curved layer.

In a light emitting display device according to one embodiment of the present disclosure, the pixel electrode, the intermediate layer, and the common electrode may be disposed along a corrugated surface of the curved structure.

In a light emitting display device according to one embodiment of the present disclosure, the pixel electrode may comprise a reflective electrode.

In a light emitting display device according to one embodiment of the present disclosure, the curved structure may comprise a metal.

A light emitting display device according to one embodiment of the present disclosure may further comprise a thin-film transistor disposed between the substrate and the curved structure and a planarization layer to cover the thin-film transistor. The thin-film transistor may be electrically connected to the pixel electrode.

A light emitting display device according to one embodiment of the present disclosure may comprise a substrate comprising a first light emitting unit, a second light emitting unit, and a third light emitting unit, a first pixel electrode, a second pixel electrode, and a third pixel electrode on the substrate in correspondence with the first to third light emitting units, respectively, an intermediate layer and a common electrode sequentially disposed on the first pixel electrode, the second pixel electrode, and the third pixel electrode, a first curved layer between the substrate and each of the first to third pixel electrodes and a second curved layer between the first curved layer and each of the first to third pixel electrodes, the second curved layer comprising a plurality of patterns spaced apart from each other. The first curved layer at one of the first to third light emitting units may have a curvature different from curvatures of first curved layers in remaining ones of the first to third light emitting units.

In a light emitting display device according to one embodiment of the present disclosure, the second curved layer may have a curvature greater than a maximum curvature of curvatures of the first curved layers at the first to third light emitting units.

In a light emitting display device according to one embodiment of the present disclosure, the first curved layer and the second curved layer may comprise an organic material.

In a light emitting display device according to one embodiment of the present disclosure, the curved structure may comprise a metal.

The light emitting display device according to the embodiment of the present disclosure may implement Environmental/Social/Governance (ESG) by reducing production energy consumption through process optimization. Accordingly, the number of layer structures in the light emitting display device may not be increased or reduced. Production energy required to manufacture the display device may be reduced, and the use of hazardous or regulated substances may also be reduced, thereby facilitating recycling and enabling the implementation of environmentally friendly display devices.

The effects achievable through the present disclosure are not limited to the above-mentioned effects, and other various effects may be directly or implicitly disclosed in the above detailed description of the present disclosure.

What is claimed is:

1. A light emitting display device, comprising:
a substrate;
a plurality of light emitting units;
a plurality of light emitting elements on the substrate, each of the plurality of light emitting elements comprising a pixel electrode corresponding to one of the plurality of light emitting units, an intermediate layer on the pixel electrode, and a common electrode on the intermediate layer; and
a curved structure between the substrate and each of the plurality of light emitting elements,
wherein the curved structure comprises:
a first curved layer at a corresponding light emitting unit; and
a second curved layer comprising a plurality of patterns disposed on the first curved layer and spaced apart from each other.

2. The light emitting display device according to claim 1, wherein the first curved layer at one of the plurality of light emitting units has a curvature different from curvatures of first curved layers at adjacent light emitting units.

3. The light emitting display device according to claim 1, wherein the second curved layer has a curvature greater than a curvature of the first curved layer.

4. The light emitting display device according to claim 1, wherein the plurality of light emitting units comprises:
a first light emitting unit configured to emit light of a first color;
a second light emitting unit configured to emit light of a second color having a longer wavelength than the first color; and
a third light emitting unit configured to emit light of a third color having a shorter wavelength than the first color, and
wherein the first curved layer at the first light emitting unit, the first curved layer at the second light emitting unit, and the first curved layer at the third light emitting unit have different curvatures.

5. The light emitting display device according to claim 1, wherein the plurality of light emitting units comprise:
a first light emitting unit configured to emit light of a first color;
a second light emitting unit configured to emit light of a second color having a longer wavelength than the first color; and
a third light emitting unit configured to emit light of a third color having a longer wavelength than the second color, and
wherein the first curved layer at one of the first, second, and third light emitting units has a curvature different from curvatures of first curved layers at remaining ones of the first, second, and third light emitting units.

6. The light emitting display device according to claim 1, wherein the plurality of light emitting units comprise:
a first light emitting unit configured to emit light of a first color;
a second light emitting unit configured to emit light of a second color having a longer wavelength than the first color; and
a third light emitting unit configured to emit light of a third color having a longer wavelength than the second color, and
wherein the first curved layer at the third light emitting unit has a largest curvature.

7. The light emitting display device according to claim 1, wherein the plurality of light emitting units comprise:
a first light emitting unit configured to emit light of a first color;
a second light emitting unit configured to emit light of a second color having a longer wavelength than the first color; and
a third light emitting unit configured to emit light of a third color having a longer wavelength than the first color, and
wherein the first curved layer at the second light emitting unit has a largest curvature.

8. The light emitting display device according to claim 4, wherein the first curved layer at the first light emitting unit, the first curved layer at the second light emitting unit, and the first curved layer at the third light emitting unit comprise a same material.

9. The light emitting display device according to claim 4, wherein the second curved layer at the first light emitting unit, the second curved layer at the second light emitting unit, and the second curved layer at the third light emitting unit have a same curvature.

10. The light emitting display device according to claim 4, wherein the second curved layer has a curvature greater than a maximum curvature of the different curvatures.

11. The light emitting display device according to claim 1, wherein the first curved layer and the second curved layer comprise an organic material.

12. The light emitting display device according to claim 1, wherein the pixel electrode is in contact with the second curved layer and a portion of the first curved layer not covered by the second curved layer.

13. The light emitting display device according to claim 12, wherein the pixel electrode, the intermediate layer, and the common electrode are disposed along a corrugated surface of the curved structure.

14. The light emitting display device according to claim 1, wherein the pixel electrode comprises a reflective electrode.

15. The light emitting display device according to claim 1, wherein the curved structure comprises a metal.

16. The light emitting display device according to claim 1, further comprising:
a thin-film transistor disposed between the substrate and the curved structure; and
a planarization layer to cover the thin-film transistor,
wherein the thin-film transistor is electrically connected to the pixel electrode.

17. A light emitting display device, comprising:
a substrate;
a first light emitting unit, a second light emitting unit, and a third light emitting unit;
a first pixel electrode, a second pixel electrode, and a third pixel electrode on the substrate in correspondence with the first, second, and third light emitting units, respectively;
an intermediate layer and a common electrode sequentially disposed on the first pixel electrode, the second pixel electrode, and the third pixel electrode;
a first curved layer between the substrate and each of the first, second, and third pixel electrodes; and
a second curved layer between the first curved layer and each of the first, second, and third pixel electrodes, the second curved layer comprising a plurality of patterns spaced apart from each other,
wherein the first curved layer at one of the first, second, and third light emitting units has a curvature different from curvatures of first curved layers in remaining ones of the first, second, and third light emitting units.

18. The light emitting display device according to claim 17, wherein the second curved layer has a curvature greater than a maximum curvature of curvatures of the first curved layers at the first, second, and third light emitting units.

19. The light emitting display device according to claim 17, wherein the first curved layer and the second curved layer comprise an organic material.

20. The light emitting display device according to claim 17, wherein at least one of the first curved layer and the second curved layer comprises a metal.
